(19) United States
(12) Patent Application Publication
(10) Pub. No.: US 2026/0068280 A1
(43) Pub. Date: Mar. 5, 2026

(54) INTEGRATED CIRCUIT DEVICE WITH GATE ANTI-TYPE DOPED REGION

(71) Applicant: Taiwan Semiconductor Manufacturing Company, Ltd., Hsinchu (TW)

(72) Inventors: Chia-Yu Wei, Hsinchu City (TW); Chia-Cheng Ho, Hsinchu City (TW); Po-Yu Chiang, Hsinchu City (TW); Wen Chieh Ho, Hsinchu County (TW); Victor Chiang Liang, Hsinchu City (TW)

(21) Appl. No.: 18/822,762

(22) Filed: Sep. 3, 2024

(51) Int. Cl. H01L 29/49; H01L 21/28; H01L 27/092; H01L 29/51; H01L 29/66; H01L 29/78

(52) U.S. Cl. CPC H10D 64/671; H10D 84/858; H10D 30/027; H10D 30/60; H10D 64/693

(57) ABSTRACT

Some embodiments relate to an integrated circuit (IC) device that includes a substrate including a P-well region and a dielectric structure. The dielectric structure is disposed at a surface of the substrate, extends downward into the substrate, and is located at a lateral perimeter of the P-well region. The IC device further includes a dielectric layer disposed over the P-well region and extends laterally over the dielectric structure. The IC device also includes an N+ gate structure disposed over the dielectric layer and includes at least one P+ region located over the P-well region of the substrate and the dielectric structure.

### BACKGROUND

Ultra-low-power complementary metal-oxide-semiconductor (CMOS) voltage reference circuits have become important in the implementation of various types of integrated circuit (IC) devices, including, but not limited to, display drivers, digital-to-analog converters (DACs), and analog-to-digital converters (ADCs). A corresponding area of focus is the provision of a highly accurate and precise voltage reference over a range of process technologies in a cost-effective manner.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic view of some embodiments of a complementary metal-oxide-semiconductor (CMOS)-only voltage reference circuit, according to the present disclosure.

FIG. 2 illustrates a cross-sectional view of some embodiments of a shallow trench isolation (STI) structure possessing a “divot” feature, as exhibited in a normal gate device (NGD) of a CMOS voltage reference circuit, that may adversely affect accuracy of a CMOS voltage reference circuit, according to the present disclosure.

FIG. 3 illustrates a graph of current-voltage (IV) curves of an NGD at different bias voltages that may exhibit a “hump” effect cause by a divot feature that adversely affects CMOS voltage reference accuracy, according to the present disclosure.

FIGS. 4A and 4B illustrate a layout view and a cross-sectional view, respectively, of an NGD that includes a gate anti-type doped region, according to the present disclosure.

FIG. 5 illustrates an example current flow in an NGD as influenced by a gate anti-type doped region, according to the present disclosure.

FIG. 6 illustrates a graph of IV curves exhibiting example gamma values useful for quantifying the effect on threshold voltage by the hump effect of an NGD.

FIG. 7 illustrates a graph of IV curves and associated gamma values for NGDs that implement and do not implement a gate anti-type doped region, according to the present disclosure.

FIG. 8 illustrates a graph of example temperature coefficient versus voltage reference performance for NGDs that implement and do not implement a gate anti-type doped region, according to the present disclosure.

FIGS. 9A through 9F illustrate cross-sectional views of some embodiments of an NGD implementing a gate anti-type doped region and a corresponding flipped-gate device (FGD) at multiple stages of fabrication, according to the present disclosure.

FIG. 9G illustrates a different cross-sectional view of the FGD of FIG. 9F, according to the present disclosure.

FIG. 9H illustrates a plan view of FGD 104 associated with FIG. 9G, according to the present disclosure.

FIG. 10 illustrates a methodology of forming some embodiments of an NGD including a gate anti-type doped region of FIGS. 9A through 9F, according to the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

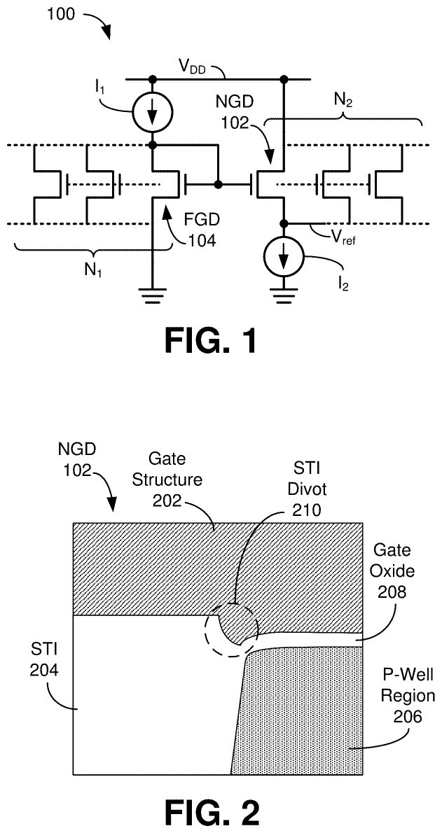

FIG. 1 illustrates a schematic view of some embodiments of a complementary metal-oxide-semiconductor (CMOS)-only voltage reference circuit 100, according to the present disclosure. As shown, voltage reference circuit 100 may include a normal gate transistor device (NGD) 102 and a flipped gate transistor device (FGD) 104 whose gate terminals are connected together and to a drain terminal of FGD 104. Further, between a first voltage terminal (e.g., drain voltage V_{DD}) and a drain terminal of FGD 104 may be a first current source I₁. A second current source I₂ may connect a source terminal of NGD 102 to a second voltage terminal (e.g., a ground reference or a source voltage V_{SS}). Current sources I₁ and I₂ may include one or more transistors and/or other devices, but such sources are not discussed in greater detail herein. In some embodiments, a plurality (e.g., N₁) of FGDs 104 may be coupled together in parallel, and a plurality (e.g., N₂) of NGDs 102 may be coupled together in parallel, in which the parallel devices may be coupled together at one or more of their gate, source, and drain terminals.

In some embodiments, NGD 102 may be a standard or “normal” nMOS transistor device that may include a p-doped (P+) substrate, n-doped (N+) drain and source regions in the substrate, and a N+ polycrystalline silicon (polysilicon) gate structure positioned over the substrate. Thus, in a normal gate device NGD 102, the doping (e.g., implantation or diffusion) of the gate structure (N+) is opposite of that of the substrate (P+). FGD 104 may be an nMOS transistor device that also includes a P+ substrate and N+ drain and source regions in the substrate. However, FGD 104 further includes a “flipped” gate structure, which may include a P+ polysilicon gate with one or more anti-type doped (N+) regions (e.g., at lateral edges of the gate structure). Thus, as employed herein, the substrate and gate structure of FGD 104 are of the same or similar doping (P+), and are thus “flipped” compared to NGD 102. Also, as used herein, source/drain region(s) may refer to a source or a drain, individually or collectively, dependent upon the context.

In some embodiments, voltage reference circuit 100 may exploit the polysilicon work function difference between the one or more NGDs 102 and FGDs 104 to create a voltage reference V_{ref}. Further, in some embodiments, voltage reference V_{ref} may be determined by the current density I₁/N₁ of the one or more FGDs 104 and the current density I₂/N₂ of the one or more NGDs 102. Additionally, the subthreshold current ratio and associated standard deviation of NGD 102 and FGD 104 may impact voltage reference V_{ref} accuracy due to NGD 102 and FGD 104 being operated in the subthreshold range in voltage reference circuit 100. In some embodiments, voltage reference V_{ref} generated by voltage reference circuit 100 may be specified as follows:

$${V}_{ref} = ( {V}_{t , FGD} - {V}_{t , NGD} ) + {nV}_{T} ln ( \frac{{I}_{1}}{{I}_{2}} \frac{{N}_{2}}{{N}_{1}} )$$

V_{t,FGD} is the threshold voltage of FGD 104, V_{t,NGD} is the threshold voltage of NGD 102, n is an ideality factor (e.g., the quality factor or emission coefficient of the Shockley ideal diode equation), and V_{T} is the thermal voltage (e.g., also from the Shockley ideal diode equation).

In operating NGD 102 and FGD 104 in the subthreshold region, a phenomenon known as the “corner effect” may have an effect on the performance (e.g., accuracy, precision, and/or thermal stability) of voltage reference circuit 100. Generally, the corner effect is a leakage current enhancement at the edges of active areas in CMOS transistors that are isolated by shallow trench isolation (STI) structures. In some cases, the corner effect may be affected by the presence of a “divot” feature often associated with an STI structure.

FIG. 2 illustrates a cross-sectional view of some embodiments of a dielectric (STI) structure 204 possessing such a divot feature 210, as exhibited in NGD 102, that may adversely affect the performance of voltage reference circuit 100, according to the present disclosure. As shown in FIG. 2, dielectric structure 204 may be formed laterally to a P-well region 206 of a substrate, over which a gate structure 202 and a dielectric layer (e.g., gate oxide structure) 208 may be formed. The presence, shape, size, and/or depth of divot feature 210 may be difficult to control in 90-nanometer (nm) technology and other low-cost processes. As a result, shape variations of divot feature 210 may cause a corresponding variation (e.g., reduction) in threshold voltage Vₜ of NGD 102 due to the greater control imposed by gate structure 202 in the vicinity of divot feature 210, which may result in the development of a “hump” effect.

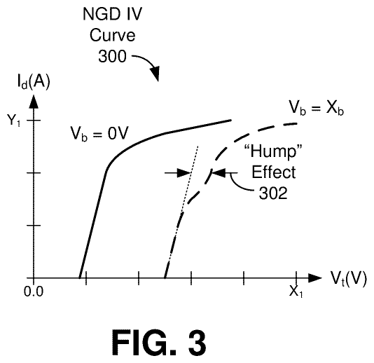

FIG. 3 illustrates a graph of current-voltage (IV) curves 300 of NGD 102 that may exhibit a hump effect 302 at different bias voltages V_{b}, according to the present disclosure. Hump effect 302 manifests as a reduction in threshold voltage Vₜ at lower drain currents I_{d}. As shown in FIG. 3, hump effect 302 may become more noticeable or enhanced with the presence of, or increase in, back bias voltage (e.g., V_{b}=X_{b}, as depicted in FIG. 3, where X_{b} may be in the range of 0.5 volts (V) to 5.0 V in some embodiments). This reduction in threshold voltage Vₜ may cause reduced accuracy and repeatability of voltage reference V_{ref} provided by voltage reference circuit 100. Also, as depicted in FIG. 3, in some embodiments, voltage X₁ may range from 0.5 V to 5.0 V, and current Y₁ may range from 1 nanoamp (nA) to 1 milliamp (mA), where threshold voltage Vₜ is shown on a linear scale and drain current I_{d} is represented on a logarithmic scale.

To address these issues, the present disclosure provides some embodiments of an integrated circuit (IC) device including an NGD transistor device (e.g., NGD 102) that includes a gate anti-type doped region that may be disposed over a gate oxide or other dielectric layer and an edge of an STI structure (e.g., at a P-well region). As used herein, an “anti-type” doped (e.g., implant) region may be a region that is oppositely doped from the surrounding regions in the particular material or structure in which it resides. In some embodiments, as described in greater detail below, the gate anti-type doped region may reduce channel current in the subthreshold region, thus possibly reducing the impact of the STI structure divot feature 210 and the associated hump effect 302, thereby improving the performance of voltage reference circuit 100. Moreover, in some embodiments, as described more fully below, the addition of the gate anti-type doped region may not incur any additional process steps associated with the minimal change in circuit layout associated with the creation of voltage reference circuit 100.

In the various embodiments discussed below, while the anti-type region is referred to as an implant region, other methods of doping, such as diffusion, may be employed to create the anti-type region, as well as other N+ and P+ regions referenced below.

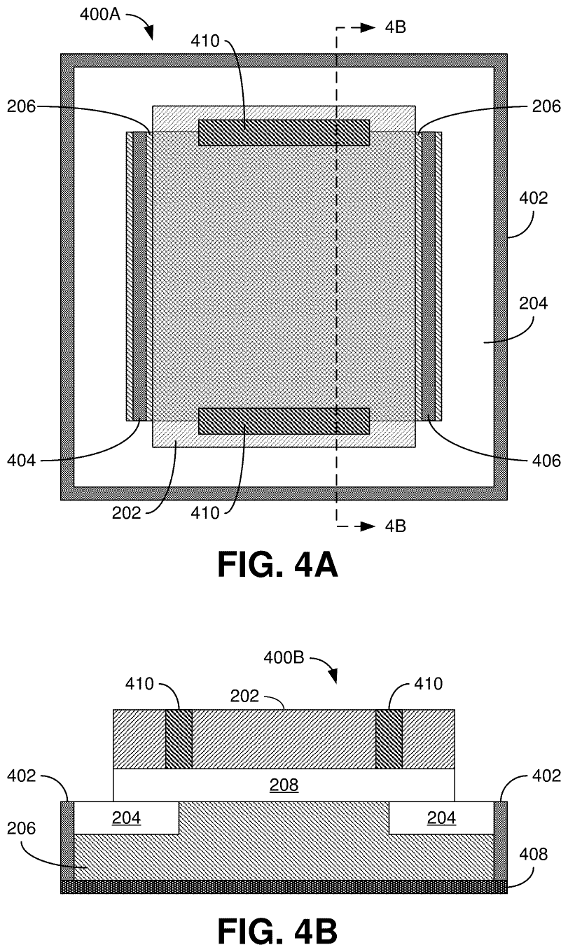

FIGS. 4A and 4B illustrate a layout view 400A and a cross-sectional view 400B, respectively, of an NGD 102 that includes a gate anti-type doped (e.g., implant) region (e.g., P+ region) 410, according to the present disclosure. More specifically, the location of cross-sectional view 400B of FIG. 4B is indicated by way of the dashed line illustrated in FIG. 4A. As shown in FIG. 4B, in some embodiments, NGD 102 may include a substrate in which a deep N-well region 408 underlies a P-well region 206, which may be laterally surrounded by an N-well region 402. In some embodiments, P-well region 206 may provide the semiconductor channel through which electrical current may flow between an N+ source region (or first N+ source-drain region) 404 and an N+ drain region (or second N+ source-drain region) 406, as depicted in both FIGS. 4A and 4B. In some embodiments, the substrate may include silicon (Si) or another semiconductor material.

In some embodiments, a dielectric structure (e.g., a shallow trench isolation (STI) structure) 204 may be formed in the substrate at P-well region 206. More specifically, in some embodiments, dielectric structure 204 may be formed at a surface of the substrate and extend downward at least partially into the substrate. Further, in some embodiments, dielectric structure 204 may be located at a lateral perimeter of P-well region 206 (e.g., along N-well region 402), as shown in FIG. 4B. Moreover, dielectric structure 204 may be disposed partially or entirely along a lateral perimeter of P-well region 206. In some embodiments, dielectric structure 204 may include silicon oxide (SiOₓ) (e.g. silicon dioxide (SiO₂)), or another oxide or dielectric material (e.g., silicon nitride (SiN), silicon carbide (SiC), carbon-doped silicon dioxide, silicon oxynitride, borosilicate glass (BSG), phosphorus silicate glass (PSG), borophosphosilicate (BPSG), fluorosilicate glass (FSG), undoped silicate glass (USG), a porous dielectric material, or the like).

In some embodiments, a dielectric layer (e.g., a gate oxide, such as silicon oxide (SiOₓ) (e.g., silicon dioxide (SiO₂)), or another oxide or dielectric material, as described above) 208 may be disposed over (e.g., atop) P-well region 206, as well as at least a portion of dielectric structure 204. In some embodiments, lateral edges of dielectric layer 208 may be located over dielectric structure 204. Further, an N+ (n-doped) gate structure 202 may be disposed over (e.g., atop) dielectric layer 208. In some embodiments, as shown in FIG. 4B, the lateral extent of N+ gate structure 202 may substantially match the lateral extent of dielectric layer 208.

In some embodiments, at least one P+ (p-doped) region 410 may be disposed within N+ gate structure 202 to serve as an anti-type doped region, as described above. As illustrated in both FIGS. 4A and 4B, two P+ regions 410 may be present, with each P+ region 410 disposed over dielectric structure 204 and P-well region 206. In some embodiments, one lateral side of P+ region 410 may reside over dielectric structure 204, while an opposing lateral side of P+ region 410 may reside over P-well region 206, but not over dielectric structure 204. Further, in some embodiments, each P+ region 410 may extend along a corresponding laterally-facing side of dielectric structure 204 perpendicular to and between first and second N+ source-drain regions 404 and 406. More particularly, a first P+ region 410 may extend over an intermediate portion of a first laterally-facing side of dielectric structure 204 that is perpendicular to a first end and a second end of dielectric layer 208, and a second P+ region 410 may extend over an intermediate portion of a second laterally-facing side of dielectric structure 204 opposite the first laterally-facing side. Further, in some embodiments, the length of the intermediate portion of the first and second laterally-facing sides of dielectric structure 204 may be at least 75% of the length of the corresponding first and second laterally-facing side. However, other percentages (e.g., 50%, 55%, 60%, 65%, or greater than 75%) for the length of the intermediate portion relative to the first and second laterally-facing sides of dielectric structure 204 may be utilized in other embodiments. Moreover, as shown in FIG. 4B, the first and second laterally-facing sides of dielectric structure 204 may face each other across a central portion of P-well region 206. Further, in some embodiments, each P+ region 410 may be entirely surrounded laterally by N+ gate structure 202. Additionally, in some embodiments, each P+ region 410 may extend from a top surface to a bottom surface of N+ gate structure 202. Also, in some embodiments, as shown in FIG. 4B, each P+ region 410 may be narrower in a plan or layout view than dielectric structure 204.

While each P+ region 410 is shown in FIGS. 4A and 4B with a particular depth, width, and length relative to other structures of NGD 102, other relative dimensions for each P+ region 410 are also possible in other embodiments.

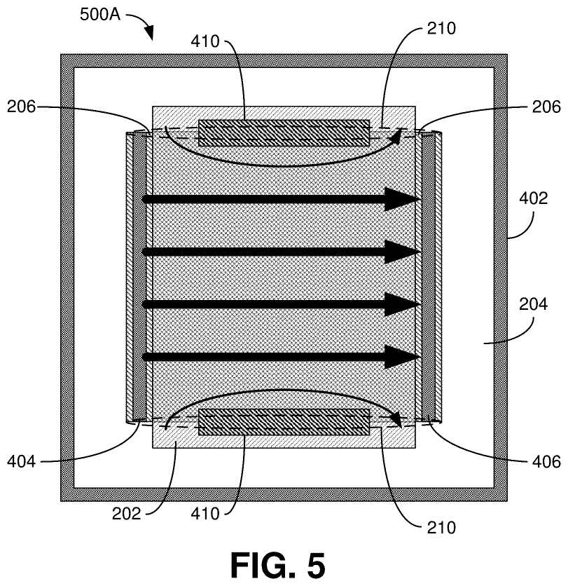

FIG. 5 illustrates, by way of a layout view 500A, an example current flow in NGD 102 as influenced by a gate anti-type doped region (e.g., P+ region 410), according to the present disclosure. As indicated, a majority of electrical current may flow between first N+ source-drain region 404 and second N+ source-drain region 406 via a channel in P-well region 206 under N+ gate structure 202. Accordingly, an amount of leakage electrical current that may pass through divot feature 210 of an edge of dielectric structure 204 under N+ gate structure 202 may be reduced or minimized by the presence of P+ regions 410, which may serve to inhibit any such leakage current from passing through the associated portion of dielectric structure 204. In some embodiments, P+ regions 410 may alter the polycrystalline silicon work function of N+ gate structure 202 at their location. This altered work function may lead to an increased threshold voltage Vₜ at those locations, thus reducing the gap between threshold voltage Vₜ at P+ regions 410 versus threshold voltage Vₜ at other positions along dielectric structure 204 near first and second N+ source-drain regions 404 and 406, resulting in a reduced hump effect 302 and lower associated leakage current.

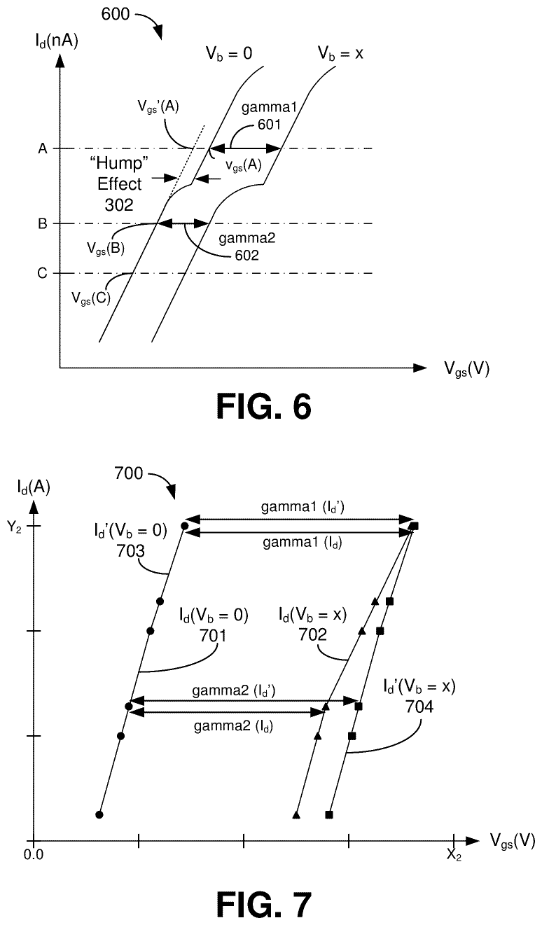

Accordingly, in some embodiments, the use of one or more P+ regions 410, when employed in NGD 102 of voltage reference circuit 100, may result in a more accurate and stable reference voltage V_{ref}. As discussed below, such accuracy and stability may be related to “gamma” values associated with NGD 102. Generally, gamma values are employed to quantify how a threshold voltage Vₜ, as represented in a gate-source voltage V_{gs}, is affected by a source-substrate reverse bias voltage V_{b}. More particularly for our purposes, FIG. 6 illustrates a graph 600 of IV curves exhibiting example gamma values that may be useful for quantifying the influence of hump effect 302 of an NGD 102 on threshold voltage Vₜ.

As described above, hump effect 302 due to divot feature 210 may affect threshold voltage Vt or gate-source voltage V_{gs} at corresponding drain currents Ia. FIG. 6 illustrates two IV curves: a first curve showing various drain currents I_{d} at corresponding gate-source voltages V_{gs} at a bias voltage V_{b}=0, and a second curve illustrating drain currents I_{d} at corresponding gate-source voltages V_{gs} at some non-zero bias voltage V_{b}=x. Given these two curves, two gamma values, gamma1 601 and gamma2 602, are defined that may provide some insight as to the influence of hump effect 302 on the accuracy and precision of the resulting reference voltage V_{ref} of voltage reference circuit 100.

Gamma (γ) may be the difference between gate-source voltages V_{gs} at a particular drain current I_{d} for two different bias voltages (e.g., a zero bias voltage V_{b}=0 (or V_{b0}) and a non-zero bias voltage (such as V_{b} in the range of −5 V to −0.5 V)). Mathematically, gamma may thus be defined as follows:

$$γ = \frac{{V}_{gs} ( {V}_{b} ) - {V}_{gs} ( {V}_{b 0} )}{\sqrt{2 {∅}_{f} - {V}_{b}} - \sqrt{2 {∅}_{f}}}$$

In the equation for gamma, 2φ_{f} is a surface potential or contact potential. Presuming a surface potential of 0.65, gamma, in some embodiments, may be as follows:

$$γ = \frac{{V}_{gs} ( {V}_{b} ) - {V}_{gs} ( {V}_{b 0} )}{\sqrt{0.65 - {V}_{b}} - \sqrt{0.65}}$$

Further, as shown in FIG. 6, gamma1 601 is the gamma value at a drain current I_{d}=A (e.g., in the range of 10-500 nanoamps (nA) in some embodiments), and gamma2 602 is the gamma value at a drain current I_{d}=B (e.g., in the range of 0.5-5 nA in some embodiments). In some embodiments, gamma1 601 is within the range of gate-source voltage V_{gs} affected by hump effect 302, and gamma2 602 is outside the range of gate-source voltage V_{gs} affected by hump effect 302. For example, a gamma value associated with a drain current I_{d}=C (e.g., in the range of 0.05 to 0.5 nA in some embodiments) may be approximately the same as gamma2 602. Thus, by comparing the difference between gamma1 601 and gamma2 602 for two different NGDs 102 (e.g., one with P+ regions 410 serving as gate anti-type regions, and one without), a judgment may be rendered regarding the relative effectiveness of P+ regions 410.

FIG. 7 illustrates a graph 700 of IV curves and associated gamma values for NGDs 102 that implement and do not implement a gate anti-type doped or implant region (e.g., P+ regions 410, as depicted in FIGS. 4A and 4B), according to the present disclosure. The drain current for NGD 102 that includes P+ regions 410 is denoted I_{d}′, while the drain current for NGD 102 that does not include P+ regions 410 is denoted I_{d}. Accordingly, in a visual review of FIG. 7, the IV curves I_{d} (V_{b}=0) 701 and I_{d} (V_{b}=x) 702 associated with NGD 102 that does not include P+ regions 410 result in a gamma2 (I_{d}) that is significantly larger than gamma2 (I_{d}) due to a prominent hump effect 302 being imposed at the non-zero bias voltage, as mentioned above in connection with FIG. 3. Oppositely, the IV curves I_{d}′ (V_{b}=0) 703 (e.g., substantially overlapping I_{d} (V_{b}=0) 701) and I_{d}′ (V_{b}=x) 704 associated with NGD 102 that includes P+ regions 410 result in a gamma1 (I_{d}′) that may be only slightly greater than gamma2 (I_{d}′), thus indicating a significant amelioration of hump effect 302. Also, as depicted in FIG. 7, in some embodiments, voltage X₂ may range from 0.5 V to 5.0 V, and current Y₂ may range from 1 nanoamp (nA) to 1 milliamp (mA), where gate-source voltage V_{gs} is shown on a linear scale and drain current I_{d} is represented on a logarithmic scale.

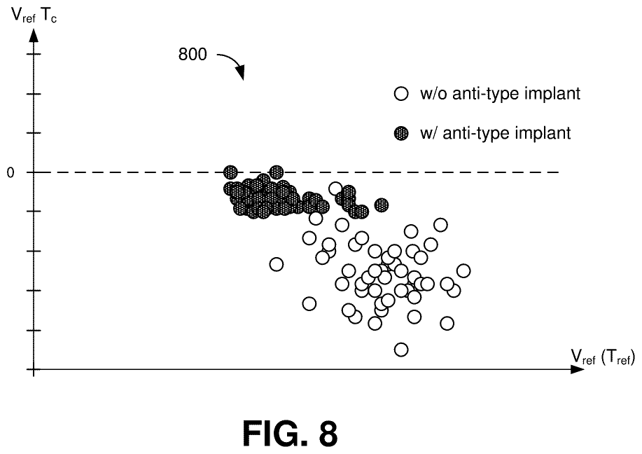

Given the reduced hump effect 302, a more accurate and precise reference voltage V_{ref} may be produced by voltage reference circuit 100 that includes NGD 102 with P+ regions 410. To that end, FIG. 8 illustrates a graph 800 of example temperature coefficient T_{c} versus voltage reference performance for NGDs 102 that implement and do not implement a gate anti-type doped region (e.g., P+ regions 410), according to the present disclosure. More specifically, FIG. 8 illustrates several measurement points of a reference voltage V_{ref} at some reference temperature T_{ref} (e.g., at 25 degrees Celsius (° C.) or some other temperature). and a corresponding temperature coefficient T_{c}, (e.g., specified in parts per million per degree Celsius (ppm/° C.)) indicating the rate of change in reference voltage V_{ref} at reference temperature T_{ref}. Qualitatively, the white test points not associated with the use of anti-type doped regions are generally further from a zero temperature coefficient T_{c}, than the shaded test points associated with the use of anti-type doped regions, indicating greater variability of reference voltage V_{ref} with respect to temperature. Further, the white test points are more dispersed both vertically and horizontally relative to the shaded test points, indicating greater variability in both the reference voltage V_{ref} and temperature coefficient T_{c} without the use of the anti-type doped regions (e.g., P+ regions 410) in NGD 102 of voltage reference circuit 100.

In view of graph 800, the distribution of the measurement points for NGDs 102 that implement and do not implement a gate anti-type doped region (e.g., P+ regions 410), thus indicate a smaller (e.g., near zero) median temperature coefficient T_{c} and a smaller standard deviation for both the reference voltage V_{ref} at reference temperature T_{ref} and the temperature coefficient T_{c} for the reference voltage V_{ref} at that temperature. Consequently, use of the anti-type doped regions may be expected to improve the accuracy and precision of a reference voltage V_{ref} provided by a voltage reference circuit 100.

Additionally, in some embodiments, while the use of an NGD 102 with anti-type doped regions (e.g., P+ regions 410) is discussed herein with respect to voltage reference circuit 100, such an NGD 102 may be employed outside the context of voltage reference circuit 100 in other embodiments to provide benefits related to a reduced leakage current induced by a divot feature of a shallow trench isolation structure.

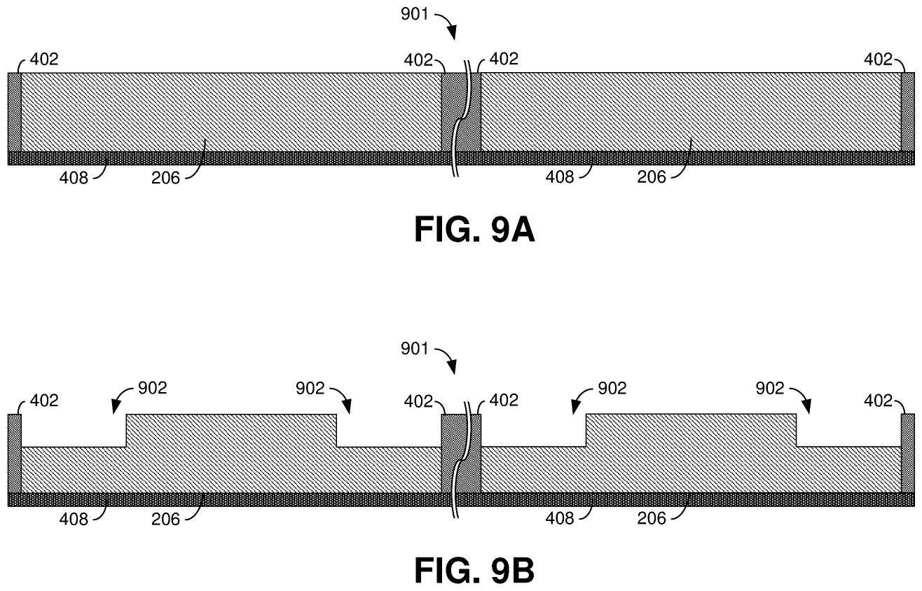

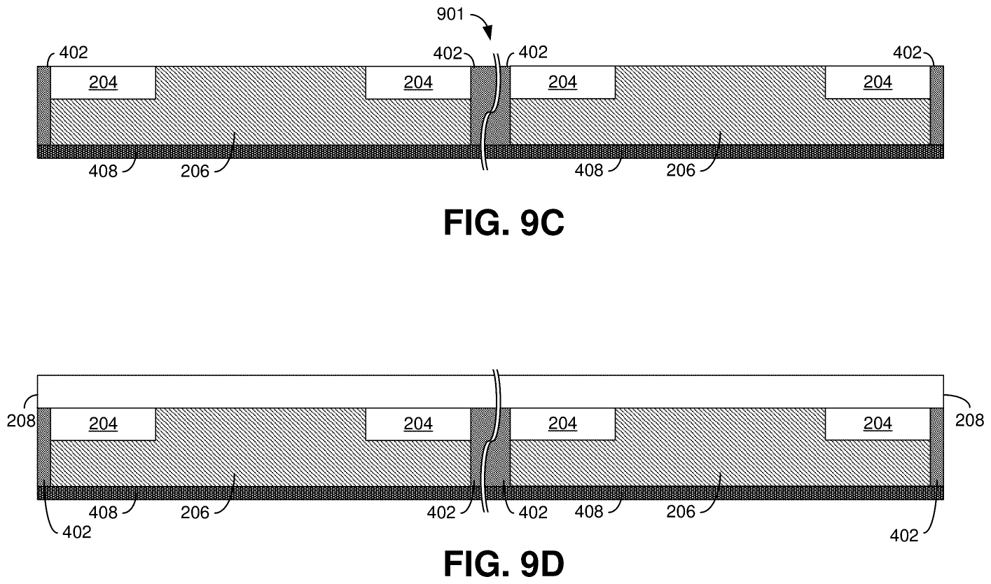

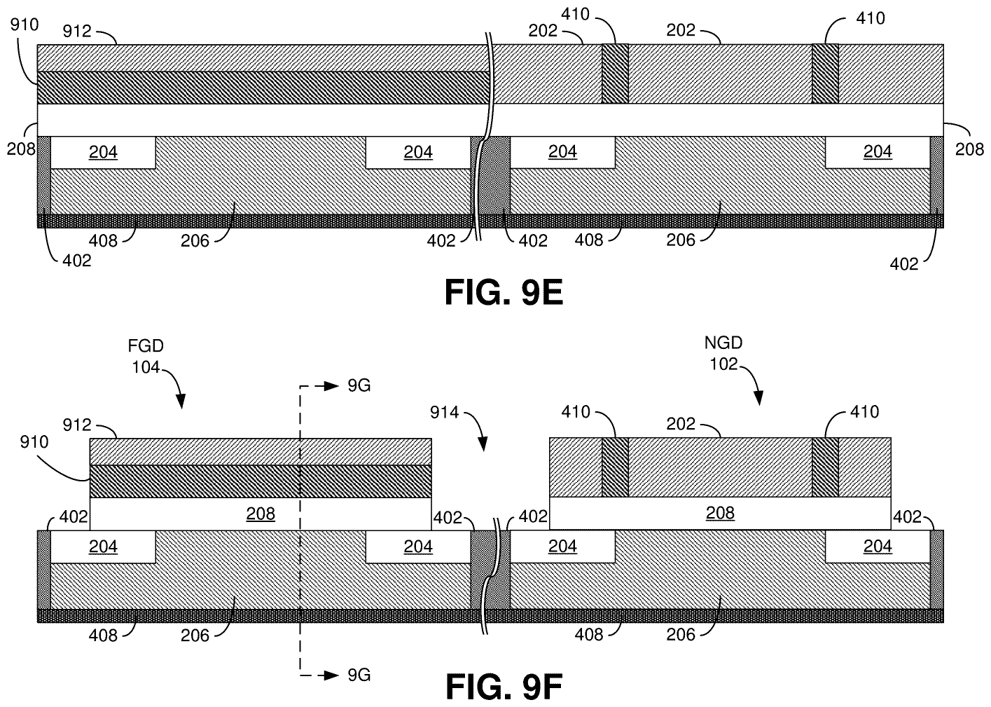

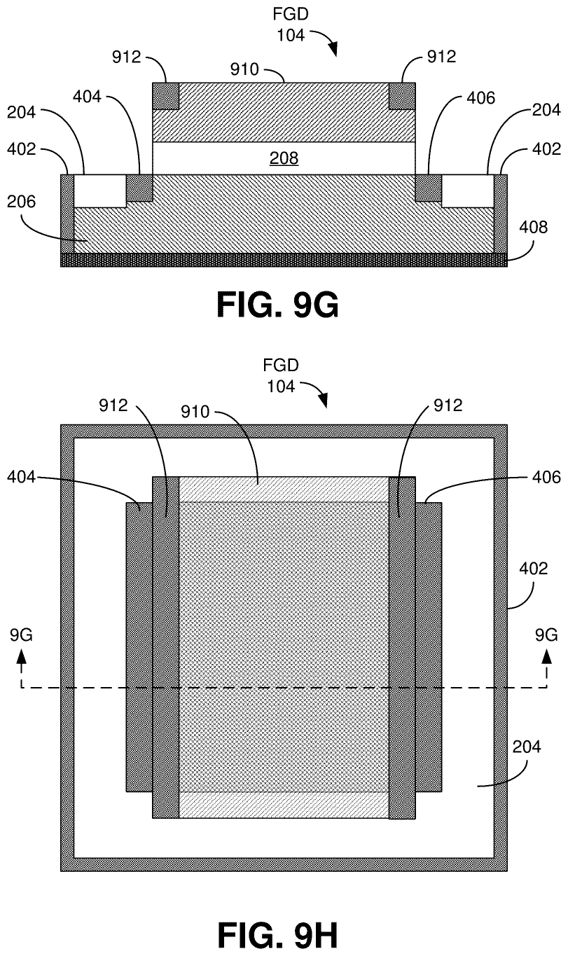

FIGS. 9A through 9F illustrate cross-sectional views of some embodiments of an IC device including an NGD 102 implementing a gate anti-type doped region (e.g., P+ regions 410) and a corresponding FGD 104 at multiple stages of fabrication, according to the present disclosure. Although FIGS. 9A through 9F are described as a series of acts, it will be appreciated that these acts are not limiting in that the order of the acts within each series can be altered in other embodiments, and the methods disclosed are also applicable to other structures. In other embodiments, some acts that are illustrated and/or described may be omitted in whole or in part.

For example, FIG. 9A illustrates the provision of a substrate 901 with doped (e.g., implanted or diffused) regions, including, but not limited to, a deep N-well region 408, over which P-well regions 206 are formed. As described in conjunction with the FIGS. 9B through 9F, left-hand P-well region 206 may constitute a portion of FGD 104, while right-hand P-well region 206 may constitute a portion of NGD 102, as described above. Further, substrate 901 may include one or more N-well regions 402 that separate the various P-well regions 206 from each other. In some embodiments, the various regions of substrate 901 may be formed by multiple implantation operations performed on associated portions of substrate 901. For example, in some embodiments, deep N-well region 408 may be formed using implantation via a lower surface of substrate 901, and using implantation of P-well regions 206 and N-well regions 402 via an upper surface of substrate 901. In some embodiments, substrate 901 may include silicon (Si) and/or other semiconductor materials.

FIG. 9B illustrates the forming (e.g., photolithography and associated etching) of trenches 902 in an upper surface of P-well regions 206 of substrate 901. In some embodiments, one or more trenches 902 may be formed within each P-well region 206 (e.g., adjacent N-well regions 402). Further, in some embodiments, each trench 902 may extend partially (e.g., less than or equal to halfway) into its corresponding P-well region 206. Moreover, as indicated in FIGS. 4A and 4B, each trench 902 may be located at a lateral perimeter at the upper surface of a corresponding P-well region 206.

FIG. 9C illustrates the forming (e.g., deposition) of dielectric material (e.g., silicon oxide (SiOₓ), such as silicon dioxide (SiO₂), or another oxide or dielectric material) to create one or more dielectric structures (e.g., shallow trench isolation (STI) structures) 204. Accordingly, dielectric structures 204 may take the form of trenches 902 of FIG. 9B, thus extending partially into corresponding P-well regions 206. Additionally, in some embodiments, each dielectric structure 204 may be located at a lateral perimeter at the upper surface of a corresponding P-well region 206. Also, in some embodiments, after deposition of the dielectric material, the creation of dielectric structures 204 may be followed by planarization of the upper surfaces of P-well regions 206, N-well regions 402, and dielectric structures 204 (e.g., using chemical-mechanical planarization (CMP)).

FIG. 9D illustrates the forming (e.g., deposition) of dielectric layer 208 over (e.g., atop) the upper surfaces of P-well regions 206, N-well regions 402, and dielectric structures 204. In some embodiments, a single dielectric layer 208 may be formed over a plurality of P-well regions 206, as depicted in FIG. 9D. As described more fully below, dielectric layer 208 may form a gate oxide (e.g., silicon oxide (SiOₓ), such as silicon dioxide (SiO₂), or another oxide or dielectric material) for the gate structure of each transistor device associated with each P-well region 206.

FIG. 9E illustrates the forming (e.g., deposition) of a conductive layer (e.g., polycrystalline silicon (polysilicon) or another metallic and/or conductive material) over dielectric layer 208, followed by the forming (e.g., doping, such as by implantation or diffusion) of various P+ and N+ regions within the conductive layer to create, for example, N+ gate structure 202 (e.g., for NGD 102) and a P+ gate structure 910 (e.g., for FGD 104), as well as P+ regions 410 (e.g., for NGD 102) and N+ region 912 (e.g., for FGD 104). As described above, P+ regions 410 may serve as anti-type doped or implant regions, as described above, while N+ region 912 may serve to provide self-aligned formation of n-doped source-drain regions (not explicitly shown in FIG. 9E) for FGD 104. In some embodiments, n-type dopants for N+ gate structure 202 and N+ region 912 may include arsenic (As), phosphorous (P), or another n-type dopant material. Also, in some embodiments, p-type dopants for P+ gate structure 910 and P+ regions 410 may include boron (B), boron difluoride (BF₃), or another p-type dopant material.

In some embodiments, given the use of both p-type and n-type regions in both NGD 102 and FGD 104, the implantation of P+ regions 410 may be performed concurrently with other P+ regions (e.g., P+ gate structure 910 of FGD 104, or P+ source-drain regions of pMOS transistor devices not shown or discussed herein). Consequently, P+ regions 410 may be created without adding any additional IC process steps, in some embodiments.

FIG. 9F illustrates the forming (e.g., photolithography and associated etching) of various trenches 914 (e.g., areas over N-well regions 402) to form the gates and related dielectric (e.g., gate oxide) structures for NGD 102 and FGD 104. In some embodiments, P+ gate structure 910 and N+ gate structure 202 are electrically connected together for use in voltage reference circuit 100. In some embodiments, formation of additional structures, such as additional dielectric layers, conductive (e.g., metal) vias, conductive (e.g., metal) layers, and so on (not shown in FIG. 9F) may follow the forming of trenches 914.

FIG. 9G illustrates a different cross-sectional view of FGD 104, as indicated by way of the dashed arrow in FIG. 9F, according to the present disclosure. Further, FIG. 9H illustrates a plan view of FGD 104, with the cross-section of FIG. 9G indicated therein. As illustrated, an N+ region 912 may be provided along each upper-side edge of P+ gate structure 910. In some embodiments, N+ regions 912 may be formed at the same time as first N+ source-drain region 404 and second N+ source-drain region 406 (e.g., to facilitate the self-aligned formation of first N+ source-drain region 404 and second N+ source-drain region 406 of FGD 104, as mentioned above). Further, in some embodiments, as shown in FIGS. 9F and 9H, N+ regions 912 may extend along an entirety of P+ gate structure 910, first N+ source-drain region 404, and/or second N+ source-drain region 406.

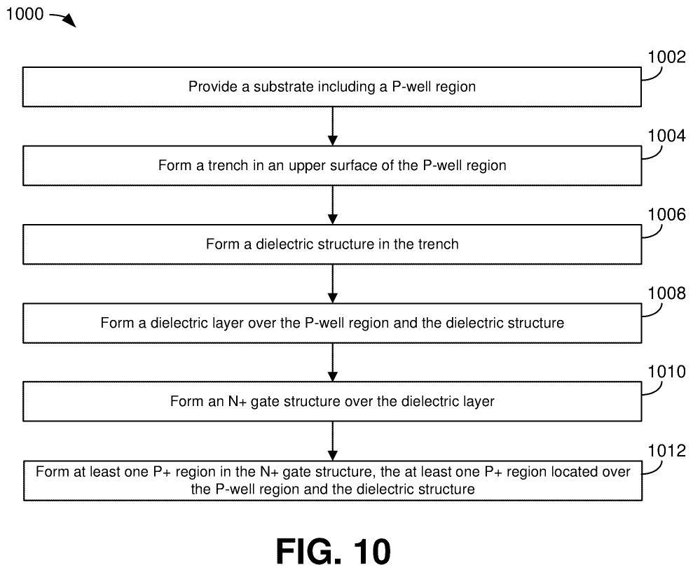

FIG. 10 illustrates a methodology 1000 of forming some embodiments of an IC device including NGD 102 that includes a gate anti-type doped (e.g., implant) region (e.g., for voltage reference circuit 100) of FIGS. 9A through 9F, according to the present disclosure. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At Act 1002, for example, a substrate (e.g., substrate 901) may be provided that includes a P-well region (e.g., P-well region 206). FIG. 9A illustrates a cross-sectional view of some embodiments corresponding to Act 1002.

At Act 1004, at least one trench (e.g., trench 902 of FIG. 9B) may be formed in an upper surface of the P-well region. FIG. 9B illustrates a cross-sectional view of some embodiments corresponding to Act 1004.

At Act 1006, a dielectric structure (e.g., dielectric structure 204 of FIG. 9C) may be formed in the trench. As indicated above, in some embodiments, the forming of the dielectric structure may be followed by planarization of the dielectric structure and the P-well region (e.g., via CMP). FIG. 9C illustrates a cross-sectional view of some embodiments corresponding to Act 1006.

At Act 1008, a dielectric layer (e.g., dielectric layer 208 of FIG. 9D) may be formed over the P-well region and the dielectric structure. FIG. 9D illustrates a cross-sectional view of some embodiments corresponding to Act 1008.

At Act 1010, an N+ gate structure (e.g., N+ gate structure 202 of FIG. 9E) may be formed over the dielectric layer. Further, at Act 1012, at least one P+ region (e.g., P+ region 410 of FIG. 9E) may be formed in the N+ gate structure, in which the at least one P+ region may be located over the P-well region and the dielectric structure. FIG. 3E illustrates a cross-sectional view of some embodiments corresponding to Acts 1010 and 1012. In some embodiments, the forming of the dielectric layer, the N+ gate structure, and the at least one P+ region may further involve the selective removal of material, as depicted in FIG. 9F, to form a separate NGD 102 that includes an anti-type doped region, as described in detail above.

Some embodiments relate to an integrated circuit (IC) device. The device includes: a substrate including a P-well region and a dielectric structure, the dielectric structure disposed at a surface of the substrate, extending downward into the substrate, and located at a lateral perimeter of the P-well region; a dielectric layer disposed over the P-well region and extending laterally over the dielectric structure; and an N+ gate structure disposed over the dielectric layer and comprising at least one P+ region located over the P-well region of the substrate and the dielectric structure.

Some embodiments relate to another IC device. The device includes: a voltage reference circuit that includes a flipped-gate device (FGD) and a normal gate device (NGD). The FGD includes a first P-well region in a substrate; first and second N+ source-drain regions in the first P-well region; and a P+ gate structure disposed over the first P-well region between the first and second N+ source-drain regions in a plan view of the IC device, the P+ gate structure including a first N+ region aligned alongside the first N+ source-drain region in the plan view and a second N+ region aligned alongside the second N+ source-drain region in the plan view. The NGD includes a second P-well region in the substrate; third and fourth N+ source-drain regions in the second P-well region; and an N+ gate structure disposed over the second P-well region between the third and fourth N+ source-drain regions in the plan view, the N+ gate structure including at least one P+ region extending between the third and fourth N+ source-drain regions in the plan view, wherein the N+ gate structure is electrically connected to the P+ gate structure.

Some embodiments relate to a method. The method includes: providing a substrate including a P-well region; forming a trench in a top surface of the P-well region; forming a dielectric structure in the trench; forming a dielectric layer over the P-well region and the dielectric structure; forming an N+ gate structure over the dielectric layer; and implanting at least one P+ region in the N+ gate structure, the at least one P+ region located over the P-well region and the dielectric structure.

It will be appreciated that in this written description, as well as in the claims below, the terms “first”, “second”, “second”, “third,” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
a substrate including a P-well region and a dielectric structure, the dielectric structure disposed at a surface of the substrate, extending downward into the substrate, and located at a lateral perimeter of the P-well region;
a dielectric layer disposed over the P-well region and extending laterally over the dielectric structure; and
an N+ gate structure disposed over the dielectric layer and comprising at least one P+ region located over the P-well region of the substrate and the dielectric structure.

2. The IC device of claim 1, wherein the N+ gate structure comprises an N+ polycrystalline silicon structure.

3. The IC device of claim 1, wherein the dielectric layer comprises at least one of silicon oxide (SiOₓ), silicon nitride (SiN), silicon carbide (SiC), carbon-doped silicon dioxide, silicon oxynitride, borosilicate glass (BSG), phosphorus silicate glass (PSG), borophosphosilicate (BPSG), fluorosilicate glass (FSG), or undoped silicate glass (USG).

4. The IC device of claim 1, wherein the dielectric structure is disposed along an entirety of the lateral perimeter of the P-well region.

5. The IC device of claim 1, the substrate further comprising:
a first N+ source-drain region disposed near a first end of the dielectric layer; and
a second N+ source-drain region disposed near a second end of the dielectric layer opposite the first end.

6. The IC device of claim 5, wherein the at least one P+ region comprises:
a first P+ region extending over an intermediate portion of a first laterally-facing side of the dielectric structure that is perpendicular to the first end and the second end of the dielectric layer; and
a second P+ region extending over an intermediate portion of a second laterally-facing side of the dielectric structure opposite the first laterally-facing side.

7. The IC device of claim 6, wherein:
the intermediate portion of the first laterally-facing side of the dielectric structure comprises at least 75% of a length of the first laterally-facing side; and
the intermediate portion of the second laterally-facing side of the dielectric structure comprises at least 75% of a length of the second laterally-facing side.

8. The IC device of claim 6, wherein:
the first laterally-facing side of the dielectric structure faces a central portion of the P-well region of the substrate; and
the second laterally-facing side of the dielectric structure faces the first laterally-facing side of the dielectric structure.

9. The IC device of claim 1, wherein the at least one P+ region is entirely laterally surrounded by the N+ gate structure.

10. The IC device of claim 1, wherein the at least one P+ region extends from a top surface of the N+ gate structure to a bottom surface of the N+ gate structure.

11. An integrated circuit (IC) device, comprising:
a voltage reference circuit comprising:
a flipped-gate device (FGD) comprising:
a first P-well region in a substrate;
first and second N+ source-drain regions in the first P-well region; and
a P+ gate structure disposed over the first P-well region between the first and second N+ source-drain regions in a plan view of the IC device, the P+ gate structure including a first N+ region aligned alongside the first N+ source-drain region in the plan view and a second N+ region aligned alongside the second N+ source-drain region in the plan view; and
a normal gate device (NGD) comprising:
a second P-well region in the substrate;
third and fourth N+ source-drain regions in the second P-well region; and
an N+ gate structure disposed over the second P-well region between the third and fourth N+ source-drain regions in the plan view, the N+ gate structure including at least one P+ region extending between the third and fourth N+ source-drain regions in the plan view, wherein the N+ gate structure is electrically connected to the P+ gate structure.

12. The IC device of claim 11, wherein the voltage reference circuit further comprises:
a first current source coupling a first voltage terminal to a drain terminal of the FGD; and
a second current source coupling a source terminal of the NGD to a second voltage terminal, wherein the source terminal provides a reference voltage.

13. The IC device of claim 11, wherein the at least one P+ region is located over the second P-well region and a dielectric structure disposed in the substrate, the dielectric structure disposed at a surface of the substrate, extending downward into the substrate, and located at a lateral perimeter of the P+ well region.

14. The IC device of claim 13, the NGD further comprising:
a dielectric layer disposed between the second P-well region and the N+ gate structure;
wherein the third N+ source-drain region is disposed near a first end of the dielectric layer;
wherein the fourth N+ source-drain region is disposed near a second end of the dielectric layer opposite the first end; and
wherein the at least one P+ region comprises:
a first P+ region extending over an intermediate portion of a first laterally-facing side of the dielectric structure that is perpendicular to the first end and the second end of the dielectric layer; and
a second P+ region extending over an intermediate portion of a second laterally-facing side of the dielectric structure opposite the first laterally-facing side.

15. The IC device of claim 14, wherein:
the first laterally-facing side of the dielectric structure faces a central portion of the second P-well region of the substrate; and
the second laterally-facing side of the dielectric structure faces the first laterally-facing side of the dielectric structure.

16. The IC device of claim 11, wherein the at least one P+ region is entirely laterally surrounded by the N+ gate structure and extends from a top surface of the N+ gate structure to a bottom surface of the N+ gate structure.

17. A method, comprising:
providing a substrate including a P-well region;
forming a trench in an upper surface of the P-well region;
forming a dielectric structure in the trench;
forming a dielectric layer over the P-well region and the dielectric structure;
forming an N+ gate structure over the dielectric layer; and
forming at least one P+ region in the N+ gate structure, the at least one P+ region located over the P-well region and the dielectric structure.

18. The method of claim 17, further comprising:
implanting a first N+ source-drain region in the substrate near a first end of the dielectric layer; and
implanting a second N+ source-drain region in the substrate near a second end of the dielectric layer opposite the first end,
wherein implanting the at least one P+ region comprises:
implanting a first P+ region to extend over an intermediate portion of a first laterally-facing side of the dielectric structure between the first end and the second end of the dielectric layer; and
implanting a second P+ region to extend over an intermediate portion of a second laterally-facing side of the dielectric structure opposite the first laterally-facing side.

19. The method of claim 18, further comprising:
implanting a P+ region of a gate structure separate from the N+ gate structure concurrently with implanting the at least one P+ region in the N+ gate structure.

20. The method of claim 18, wherein each of the first and second P+ regions is entirely laterally surrounded by the N+ gate structure and extends from a top surface of the N+ gate structure to a bottom surface of the N+ gate structure.
